(19) United States
(12) Patent Application Publication
(10) Pub. No.: US 2025/0077951 A1
(43) Pub. Date: Mar. 6, 2025

(54) MACHINE LEARNING MODEL PARAMETER COMPRESSION

(71) Applicant: QUALCOMM Incorporated, San Diego, CA (US)

(72) Inventor: Paul Nicholas WHATMOUGH, Cambridge, MA (US)

(21) Appl. No.: 18/458,786

(22) Filed: Aug. 30, 2023

(51) Int. Cl. G06N 20/00

(52) U.S. Cl. CPC G06N 20/00

(57) ABSTRACT

Certain aspects of the present disclosure provide techniques and apparatus for improved machine learning model compression. A set of parameters for a machine learning model is accessed, where the set of parameters are formatted according to a first encoding. A converted set of parameters is generated based on applying a conversion operation to format the set of parameters according to a second encoding. A set of bit planes is generated based on applying a bit plane transformation to the converted set of parameters, and a compressed set of parameters for the machine learning model is generated based on applying a bit mask operation to one or more bit planes of the set of bit planes.

### INTRODUCTION

Aspects of the present disclosure relate to machine learning.

A wide variety of machine learning model architectures have proliferated and have been used to provide solutions for a multitude of prediction problems. Though the specific architectures may vary, machine learning models generally rely on a set of model parameters having values that are learned or trained based on training data (which may include labeled data and/or unlabeled data). In many architectures (e.g., deep learning models), a large number of such parameters (well into the billions in some cases) are used to provide better utility. Additionally, in many cases, bigger models (e.g., models having more parameters) tend to perform better (e.g., with higher prediction accuracy) and/or tend to be better suited for more complex prediction tasks. However, even comparatively small models generally have a relatively large number of parameters and have a substantial memory footprint.

Such a large number of parameters inherently incurs a significant memory and/or storage footprint, as well as a similarly vast use of other computing resources. Model size has become particularly problematic in resource-constrained scenarios, where it is desired to deploy a trained model on a device having relatively limited resources (e.g., mobile devices, embedded devices, smart vehicles, and the like). Some conventional approaches to ameliorate such concerns involve parameter compression. However, such compression-based solutions generally rely on lossy compression (involving approximation of the original parameters), which results in reduced model accuracy and reliability.

### BRIEF SUMMARY

Certain aspects provide a method, comprising: accessing a set of parameters for a machine learning model, wherein the set of parameters are formatted according to a first encoding; generating a converted set of parameters based on applying a conversion operation to format the set of parameters according to a second encoding; generating a set of bit planes based on applying a bit plane transformation to the converted set of parameters; and generating a compressed set of parameters for the machine learning model based on applying a bit mask operation to one or more bit planes of the set of bit planes.

Other aspects provide processing systems configured to perform the aforementioned methods as well as those described herein; non-transitory, computer-readable media comprising instructions that, when executed by one or more processors of a processing system, cause the processing system to perform the aforementioned methods as well as those described herein; a computer program product embodied on a computer-readable storage medium comprising code for performing the aforementioned methods as well as those further described herein; and a processing system comprising means for performing the aforementioned methods as well as those further described herein.

The following description and the related drawings set forth in detail certain illustrative features of one or more aspects.

### BRIEF DESCRIPTION OF THE DRAWINGS

The appended figures depict certain features of one or more aspects of the present disclosure and are therefore not to be considered limiting of the scope of this disclosure.

FIG. 1 illustrates an example workflow for machine learning model parameter compression.

FIG. 2 illustrates an example operation for bit plane transformations to provide machine learning model parameter compression.

FIG. 3 is a flow diagram depicting an example method for machine learning model parameter compression.

FIG. 4 is a flow diagram depicting an example method for bit plane transformation operations to provide machine learning model parameter compression.

FIG. 5 is a flow diagram depicting an example method for bit masking operations to provide machine learning model parameter compression.

FIG. 6 is a flow diagram depicting an example method for data compression.

FIG. 7 depicts an example processing system configured to perform various aspects of the present disclosure.

To facilitate understanding, identical reference numerals have been used, where possible, to designate identical elements that are common to the drawings. It is contemplated that elements and features of one aspect may be beneficially incorporated in other aspects without further recitation.

### DETAILED DESCRIPTION

Aspects of the present disclosure provide apparatuses, methods, processing systems, and computer-readable mediums for machine learning model parameter compression.

In some aspects, lossless parameter compression techniques are provided to substantially reduce the data size of the model (e.g., the memory footprint) without affecting model accuracy or performance. In some aspects, the parameters may be compressed prior to runtime (e.g., by a compiler) and decompressed at runtime (e.g., using hardware). In some aspects, by reducing the model size, memory use is reduced, increasing the effective capacity of the processing hardware that uses the model to process data. This enables efficient use of machine learning models on resource-constrained devices and/or with reduced computational expense.

In some aspects, the lossless compression techniques disclosed herein can be combined with lossy compression approaches to further decrease model size with a reduced impact on model performance (as compared to exclusive use of lossy techniques, as used in some conventional approaches).

In some aspects, model compression is achieved using a sequence of operations to transform or reshape the model data in ways that enable effective lossless compression by taking advantage of inherent distributions present in the data. In some aspects, the model parameters are converted from an initial format (e.g., a two's-complement encoding) to a target format (e.g., a sign-magnitude encoding). This conversion may enable the system to more readily take advantage of naturally occurring sparsity in the data. That is, parameters encoded using two's-complement may generally exhibit a uniform distribution of values across bit positions, while the same data encoded using sign-magnitude generally exhibits markedly different distributions of values, as discussed below in more detail.

In some aspects, these converted parameters (encoded in sign-magnitude format) can then be processed using one or more bit plane transformations to generate a set of bit planes. Because the sign-magnitude encoding reveals the underlying data distribution (e.g., where a large amount of the model sparsity is present in one or more specific bit positions across parameters), such a bit plane transformation enables targeted extraction of these sparse regions, a discussed in more detail below.

In some aspects, the bit planes may then be compressed using a bit masking operation, where some portions of data (e.g., words) having a value of zero (or some other value) can be removed, and a single mask bit can be used to indicate that the word is omitted. In some aspects, words with non-zero values (or values that do not match the masked value) may have the mask bit set to a defined value to indicate that the word is non-zero. By applying this masking operation to the bit planes (which themselves were constructed based on reformatted data that takes advantage of inherent sparsity), the techniques described herein are able to significantly reduce the size of the data (e.g., the number of bits used to encode the model parameters).

### Example Workflow for Machine Learning Model Parameter Compression

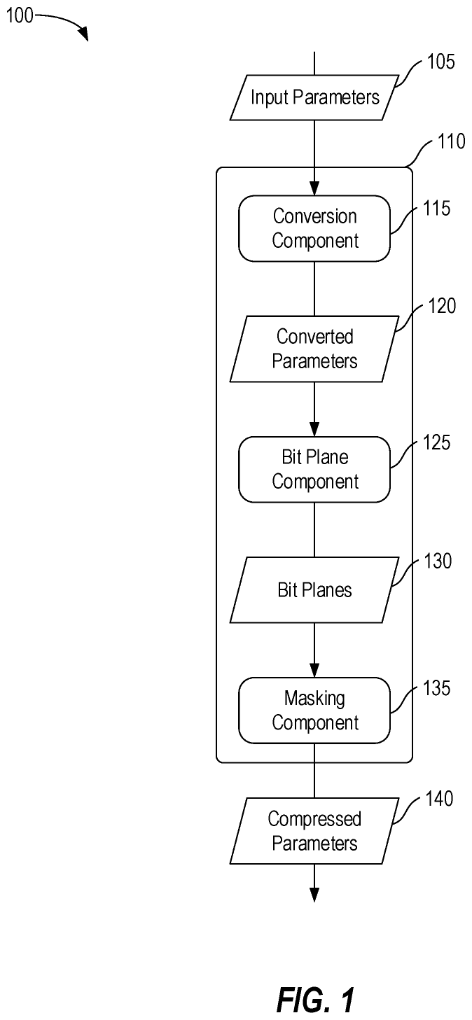

FIG. 1 illustrates an example workflow 100 for machine learning model parameter compression.

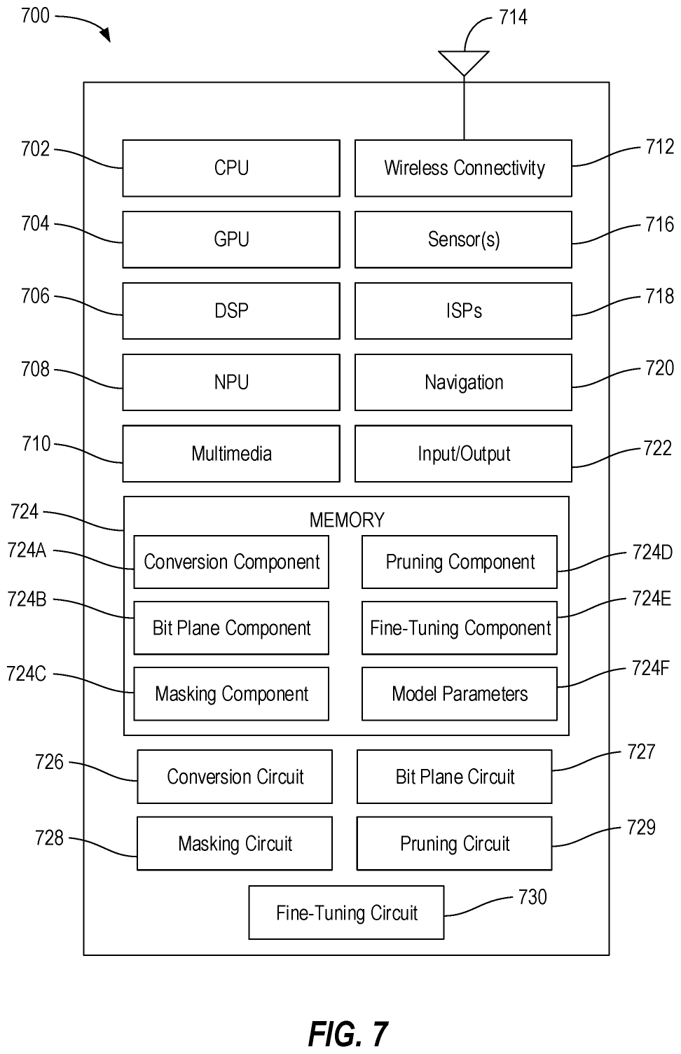

In the illustrated example, a set of input parameters 105 are accessed by a compression system 110 to generate a set of compressed parameters 140. In some aspects, the compression system 110 is a computing system used to compress machine learning models. In some aspects, the compression system 110 corresponds to the processing system 700 of FIG. 7. As used herein, “accessing” data can generally include receiving, requesting, retrieving, obtaining, collecting, generating, or otherwise gaining access to the data. For example, the compression system 110 may receive the input parameters 105 from another system or component (e.g., a training system), or the compression system 110 may itself generate the input parameters 105 (e.g., the compression system 110 may train the model).

The input parameters 105 generally correspond to parameters or variables of one or more machine learning models. For example, the parameters may be weights and/or hyperparameters of a deep neural network. In some aspects, the input parameters 105 have learned values. For instance, the compression system 110 may access the input parameters 105 after training is completed and before the model is deployed for runtime inferencing. Although some aspects of the present disclosure describe machine learning model parameters as one example set of data that can be compressed, aspects of the present disclosure are readily applicable to provide effective compression of a wide variety of data.

In some aspects, the compression system 110 is used to compress the input parameters 105 during, or as part of, compilation of the trained model and prepare the model for deployment. Although depicted as a discrete system for conceptual clarity, in some aspects, the operations of the compression system 110 may be combined or distributed across any number and variety of components and systems. The operations of the compression system 110 may generally be implemented using hardware, software, or a combination of hardware and software.

In the illustrated example, the compression system 110 includes a variety of components, including (but not limited to) a conversion component 115, a bit plane component 125, and a masking component 135. Although depicted as discrete components for conceptual clarity, the operations performed by the depicted components may similarly be combined or distributed across any number of components.

As illustrated, the conversion component 115 evaluates the input parameters 105 (encoded or formatted according to a first format) to generate a set of converted parameters 120 (encoded or formatted according to a second format). For example, in some aspects, the input parameters 105 may be encoded using a two's complement format, which is a common system used to encode or represent machine learning model parameters. Although two's complement format is used as one example format that may be used to encode the input parameters 105, the input parameters 105 may be encoded using any other alternative formats, such as one's complement. In some aspects, the converted parameters 120 use a different format, such as a sign-magnitude encoding format (or any other format that differs from the format used to encode the input parameters 105).

Both the two's-complement format and the sign-magnitude format may be used to encode positive and negative values for the input parameters 105. For example, in either encoding format, each of the input parameters 105 generally includes a sign bit as well as a set of bits used to encode magnitude. In the sign-magnitude format, the sign bit indicates the sign of the parameter (e.g., with a value of 1 indicating that the parameter has a negative value, and a value of 0 indicating that the parameter has a positive value). The magnitude of the parameter is encoded using binary in the remaining bits (e.g., for an 8-bit value, the first bit may be the sign bit and the following seven bits may encode the magnitude).

In a two's-complement format, positive numbers may be encoded in the same way as the sign-magnitude format. For negative numbers, the magnitude bits may store the two's complement of the positive version of the number (with the sign bit indicating this transformation). In some aspects, two's-complement formatting is often used in some conventional systems because such formatting can significantly simplify addition operations (eliminating evaluation of the sign bit to handle negative numbers during addition and subtraction). Furthermore, such formatting only has a single representation for a value of 0 (while sign-magnitude formatting has two: positive zero and negative zero).

As discussed above, however, data encoded using two's-complement formatting generally has a relatively uniform distribution of values across bit positions. That is, suppose the input parameters 105 comprise a set of 8-bit values. Though the input parameters 105 themselves may have a Gaussian distribution of values, the average binary value in each bit position is often uniform. For example, the first bit position, second bit position, third bit position, and so on each generally has an average value (across the input parameters 105) that approximates 0.5 (e.g., for each bit position, roughly half of the input parameters 105 have a value of 0 and roughly half have a value of 1). In contrast, sign-magnitude encoded parameters may reveal an underlying bit distribution. For example, while the sign bit (the first bit or most significant bit) may have an average value of 0.5, the first few bit(s) of the magnitude portion (e.g., the second, third, and fourth bit positions in the word, where the first bit position is the sign bit) may tend to skew substantially towards an average value of 0 (e.g., because model parameters often have relatively small magnitudes).

As illustrated, the converted parameters 120 are evaluated by the bit plane component 125 to generate a set of bit planes 130. Each of the bit planes 130 contains the binary values from a corresponding bit position in the converted parameters 120. For example, if the converted parameters 120 are encoded in 8-bit sign-magnitude format, the bit plane component 125 may generate eight bit planes 130: one that comprises the most significant bits (the sign bits across all the parameters), one that comprises the least significant bits across all parameters, and six bit planes that correspond to the remaining six bit positions.

As discussed in more detail below, in some aspects, the bit plane component 125 may use different word lengths to encode each of the bit planes 130, regardless of the word length used to encode the input parameters 105 and/or converted parameters 120. For example, the converted parameters 120 may be encoded using eight bits each, and the bit plane component 125 may use a different word length for each of the bit planes 130 (e.g., encoding the first bit plane using a word length of four bits, a second bit plane using a word length of sixteen bits, and so on). By dynamically selecting or determining the word length used to encode each of the bit planes 130, the compression system 110 may enable enhanced compression, as discussed in more detail below.

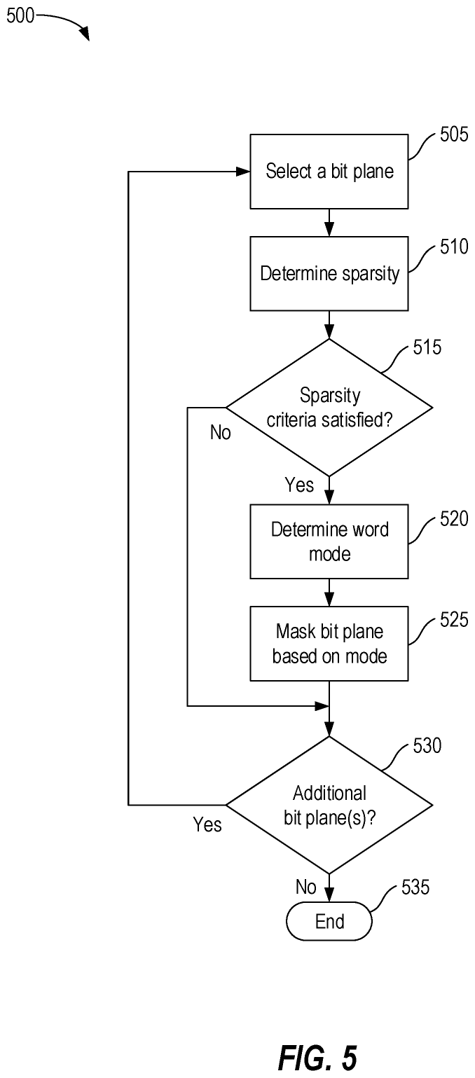

In the illustrated example, the bit planes 130 are then evaluated by the masking component 135 to generate the set of compressed parameters 140. In some aspects, the masking component 135 may generally append or prepend a mask bit to each word used to encode the bit planes 130, setting the value of the mask bit to indicate whether the accompanying word has a value of 0 (or some other defined value, as discussed below in more detail). If so (e.g., if the mask bit is set to 1), the word may be omitted. For example, an 8-bit word having a value of 0 (e.g., “00000000”) may be replaced with a single bit with a value of 1 (e.g., “1”), while an 8-bit word having a non-zero value (e.g., “10010100”) may be replaced with a 9-bit word (e.g., “010010100”) corresponding to the original eight bits, plus a mask bit having a value of 0. This aspect is further explained below, with reference to FIG. 5.

Generally, the average number of bits used to encode each word in the compressed parameters 140 depends largely on the sparsity of the bit planes 130. Higher sparsity (e.g., more words with a value of 0) generally results in increased compression (a reduced average number of bits per parameter), while lower sparsity may actually result in increased model size (e.g., an average number of bits per parameter that is higher than the average number of bits per parameter used to encode the original input parameters 105). However, as discussed above and below in more detail, the conversion component 115 and the bit plane component 125 may generally represent the input parameters 105 in such a way that the sparsity is arranged to take advantage of the masking operation, resulting in substantially reduced memory footprints.

For example, in some aspects, the number of bits used to encode the compressed parameters 140 may be approximately 40% of the number of bits used to encode the input parameters 105, approximately 50% of the number of bits used to encode the input parameters 105, or approximately 60% of the number of bits used to encode the input parameters 105, depending on the particular architecture and implementation.

The compressed parameters 140 may then be used to deploy the machine learning model (locally or on another system). For example, at runtime, an inferencing system (e.g., a computing system that uses the machine learning model to perform runtime inferencing, which may be the same system as the compression system 110 and/or may be a different computing system) may retrieve portions of the compressed parameters 140 as these portions are used to process data (e.g., extracting the parameters for each layer of a deep neural network from memory and into a processing chip when the given layer is reached during the forward pass of data through the network). The inferencing system may decode the compressed parameters 140 to recover the original input parameters 105 (e.g., on-chip) as these original parameters are used to process input data. This substantially reduces the memory footprint used to store the model, as well as reducing the bandwidth employed on the link(s) between the memory and the on-chip components used to process the data.

For example, the inferencing system may apply the inverse of the bit masking operation (e.g., removing mask bits and inserting a word with a value of 0, where the mask bit indicates that the original word was removed), the inverse of the bit plane transformation (e.g., rearranging the bits such that each word includes the bits of a given model parameter, rather than bits from multiple parameters), and/or the inverse of the conversion transformation (e.g., if two's-complement encoding is preferred or used during inferencing).

Additionally, as each of the depicted transformations may generally be implemented efficiently (e.g., using a relatively simple hardware decoder that does not consume substantial computational resources or time), the decoding process can readily be completed on-the-fly during inferencing (using hardware, software, or a combination of hardware and software) without burdening the inferencing system.

### Example Operation for Bit Plane Transformations to Provide Machine Learning Model Parameter Compression

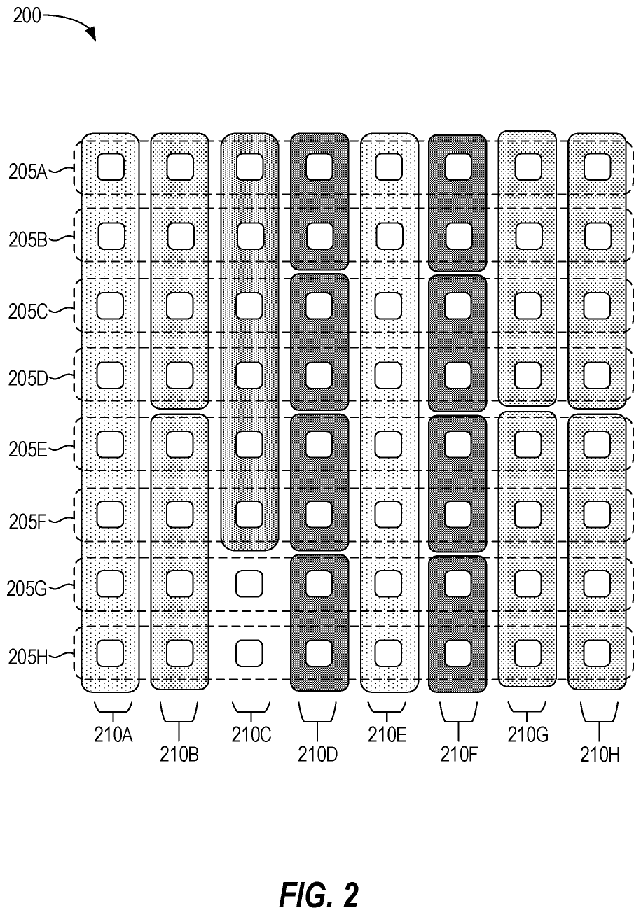

FIG. 2 illustrates an example operation 200 for bit plane transformations to provide machine learning model parameter compression. In some aspects, the illustrated example depicts a conceptual operation to generate bit planes and may be performed by a bit plane component, such as the bit plane component 125 of FIG. 1.

In the illustrated example, input words 205A-H (e.g., words used to encode the converted parameters 120 of FIG. 1) are arranged horizontally (e.g., with the input word 205A stacked on top of the input word 205B, and so on) to form a matrix of data. In the depicted example, each of the input words 205A-H (collectively, input words 205) has a word length of eight (e.g., each is encoded using eight bits), and each bit is depicted as a square with rounded corners in the illustrated example. Each input word 205 generally corresponds to a respective parameter in the machine learning model. That is, each input word 205 includes a set of eight bits encoding the value of a corresponding machine learning model parameter. Although the illustrated example depicts a word length of eight bits for the input words 205, in aspects, input words of any length may be used. Similarly, although the illustrated example depicts eight input words 205 for conceptual clarity, any number of input words 205 may be used.

As illustrated, a set of bit planes 210A-H (e.g., the bit planes 130 of FIG. 1) are generated using the input words 205. Specifically, each bit plane 210A-H (collectively, bit planes 210) includes a single bit from each of the one or more input words 205 at a corresponding bit position (e.g., where the bit plane 210A includes the most significant bit of each input word and the bit plane 210H includes the least significant bit of each input word 205).

In the illustrated example, each bit plane 210 can be encoded with a different word length by selectively choosing how many input words 205 should be used to generate the bit plane words. In the illustrated example, these word lengths are depicted using shaded boxes. For example, as illustrated, the bit plane 210A is encoded using a word length of eight (e.g., the most significant bits, one from each of eight input words 205A-H, are used to form a single word encoding the bit plane 210A). That is, when generating the bit plane 210A, the bit plane component may extract a bit from each of a set of eight input words 205 to generate each word encoding the bit plane 210A. In the illustrated example, the bit plane 210E is similarly encoded using a word length of eight.

Additionally, in the illustrated example, the bit planes 210B, 210G, and 210H are encoded with a word length of four. That is, each word of each of the bit planes 210B, 210G, and 210H is generated based on a set of four input words 205. Specifically, a first word of the bit plane 210B is generated based on the input words 205A, 205B, 205C, and 205D, and a second word of the bit plane 210B is generated based on the input words 205E, 205F, 205G, and 205H.

As another example, the bit plane 210F is encoded using a word length of two, and the bit plane 210C is encoded using a word length of six (in the illustrated example, the bits in the third bit position of the input words 205G and 205H are still included in the bit plane 210C, but are included in a separate word (not depicted) than the word used to cover the input words 205A, 205B, 205C, 205D, 205E, and 205F).

In this way, by selecting the number of input words 205 to evaluate at a time when generating words for each bit plane 210, the bit plane component can dynamically determine the word size of each bit plane in a way that enhances compressibility of the bit planes 210. For example, larger word lengths allow the system to better amortize the cost of adding a mask bit, resulting in higher reduction in word size when (longer) words are replaced with a single mask bit. However, longer word lengths also tend to result in reduced average word sparsity (e.g., reduced probability that a given word has a value of 0), which adds complexity and reduces (or eliminates) the benefits of the bit masking. As discussed in more detail below, in some aspects, the bit plane component can adaptively select the best word size for each bit plane 210 based on bit plane sparsity to maximize, or at least increase, the compression that can be achieved using the bit masking operations.

Although the illustrated example depicts input words 205 with a word length of eight, aspects of the present disclosure are readily applicable to input words 205 having any length. Further, although the illustrated example depicts eight input words 205, there may be any number of input words 205, and the word length used for each bit plane 210 may be less than, the same as, or greater than the word length of the input words 205. For example, even with input words 205 having a word length of eight, the words of a given bit plane 210 may generally be of any length (e.g., one bit plane 210 may encode the data using 256-bit words while another uses 2-bit words).

### Example Method for Machine Learning Model Parameter Compression

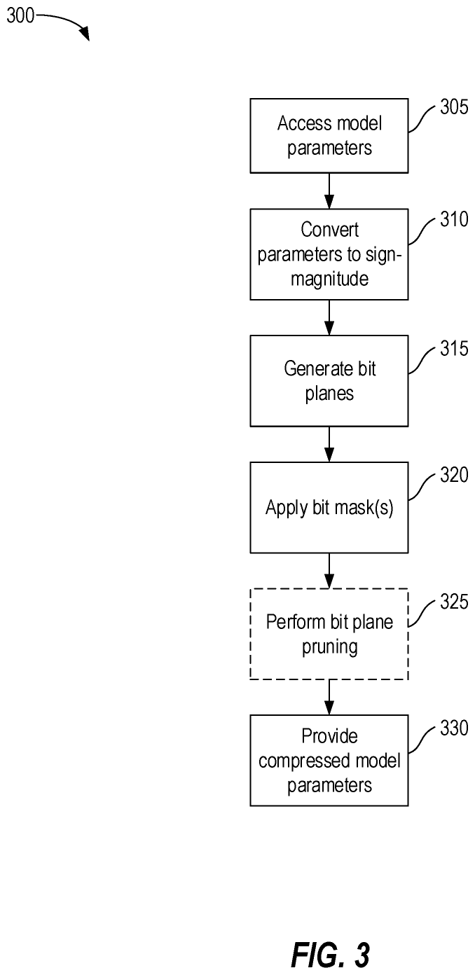

FIG. 3 is a flow diagram depicting an example method 300 for machine learning model parameter compression. In some aspects, the method 300 provides additional detail for the workflow 100 of FIG. 1. In some aspects, the method 300 is performed by a compression system, such as the compression system 110 of FIG. 1.

At block 305, the compression system accesses a set of (trained) model parameters (e.g., the input parameters 105 of FIG. 1). As discussed above, the model parameters generally comprise the parameters (or hyperparameters) of a machine learning model, each parameter having a value that was learned during a training phase based on training data. For example, for a neural network, the model parameters may include a set of weights for each of the layers of the model. In some aspects, these model parameters are encoded according to a first format (e.g., a two's-complement format).

At block 310, the compression system converts the received parameters to a second format (e.g., sign-magnitude encoding) to create converted parameters (e.g., the converted parameters 120 of FIG. 1). As discussed above, the second format (also referred to as a target format) may be selected to enhance compressibility of the model, such as by arranging the sparsity (e.g., the bits with a value of 0) in one or more specific bit positions in each parameter. In some aspects, the compression system may select and evaluate a number of encoding formats. For example, the compression system may select an alternative target encoding format using any suitable technique (including randomly or pseudo-randomly), encode the parameters using the selected format, and compress the converted data to evaluate compressibility of the selected format. The compression system may evaluate each alternative (in sequence or in parallel) to determine which target format should be used for the specific set of model parameters accessed at block 305. In some aspects, the compression system may similarly select the target format based at least in part on the architecture of the model (e.g., where each type of machine learning architecture may have a different encoding format that is optimal, or at least more suitable, for compression). For example, the compression system may refer to a defined mapping (indicating a suitable target encoding for each type of model architecture).

In some aspects, while converting to the sign-magnitude format, the compression system may optionally compress the sign bit where possible. For example, sign-magnitude encoding has a representation for both positive zero and negative zero. In some aspects, therefore, the compression system may omit or remove the sign bit if the magnitude of the parameter is zero. For example, the compression system may generate converted parameters where the magnitude portion is before the sign bit (e.g., the sign bit is the least significant bit, rather than the most significant bit). At runtime, the inferencing system may decode the magnitude first (e.g., the first seven bits). If the value is 0, the inferencing system may understand that there is no sign bit (e.g., the next word or parameter begins immediately after the magnitude portion of the current word). If the value is non-zero, the compression system may determine that the next bit is the sign bit of the current word/parameter.

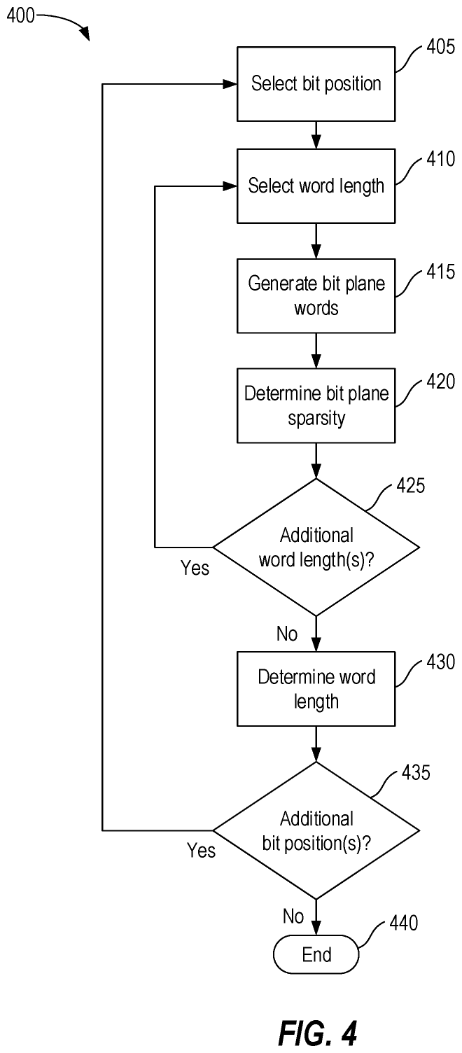

At block 315, the compression system generates a set of bit planes (e.g., the bit planes 130 of FIG. 1) based on the converted parameters. For example, as discussed above, each bit plane may correspond to or comprise the bits in a given bit position in the words used to encode the converted parameters. In some aspects, as discussed above, the compression system may determine, for each bit plane (e.g., each bit position), which word length to use to encode the bit plane. For example, the compression system may use a heuristics or rules-based approach (e.g., where a data scientist previously specified the desired word length for each bit plane based on evaluating other models), or the compression system may itself dynamically evaluate the sparsity of each bit plane to select a word length for each bit plane. One example method for generating the bit planes is discussed in more detail below with reference to FIG. 4.

At block 320, the compression system applies one or more bit masks to the bit planes (e.g., to the words used to encode the bit planes). For example, as discussed above, the compression system may prepend or append a mask bit to each bit plane word, and the compression system may set the value of this mask bit to indicate whether the corresponding word has a defined value (e.g., a value of 0). If so, the word itself may be removed, and only the mask bit may be maintained and stored. In some aspects, a value of 0 is used as the defined value (e.g., where all words having a value of 0 are replaced with a respective sign bit). In some aspects, the compression system can select another value to mask. For example, the compression system may determine the statistical mode of the words (e.g., the most common value of the bit plane words for a given bit plane), and the compression system may use this mode as the masked value for the bit plane (e.g., where words equal to or matching the mode value are masked). This can maximize, or at least increase, the compression achieved using the mask operation.

Additionally, in some aspects, the compression system may selectively determine whether to apply bit masking to each bit plane (e.g., to the words in each bit plane) based on sparsity of the bit plane, as discussed below in more detail. One example method for masking the bit plane words is discussed in more detail below with reference to FIG. 5.

At block 325, the compression system optionally performs bit plane pruning on the masked bit planes. Though pruning is generally a lossy form of compression, by pruning bit plane words (which each correspond to bits from multiple parameters), rather than directly pruning the parameters themselves, the accuracy loss may be reduced, as compared to some conventional approaches. In some aspects, to prune the bit planes, the compression system may set or determine a threshold value (e.g., defined as a hyperparameter), and the compression system may prune (e.g., set to zero) all bit plane words with a magnitude (e.g., an absolute value) that is smaller than the threshold. These pruned bit plane words may then be masked (e.g., replaced with a single mask bit during subsequent masking operations) or removed.

In some aspects, after pruning, the compression system can perform fine-tuning on the model to recover any accuracy loss. That is, the compression system may update one or more of the pruned parameters (e.g., using a relatively small set of training data). For example, in some aspects, the compression system may decode the pruned bit planes (e.g., reversing the encoding operations used to compress the data to generate the bit planes) to generate pruned parameters, update these parameters using a set of training data (e.g., using a training or model refinement operation), and then re-encode these updated pruned parameters (e.g., by applying the conversion operation, the bit plane transformation, and the bit mask operation again) to generate updated pruned bit planes.

In the illustrated example, at block 330, the compression system provides the compressed model parameters (e.g., the masked bit plane words generated at block 320, and/or the pruned masked bit plane words generated at block 325). As discussed above, providing the compressed parameters can generally include compiling the parameters or otherwise enabling access to the parameters for inferencing. For example, the compression system may transmit the compressed parameters to one or more dedicated inferencing system(s), store these parameters locally for local inferencing, and the like.

### Example Method for Bit Plane Transformation Operations to Provide Machine Learning Model Parameter Compression

FIG. 4 is a flow diagram depicting an example method 400 for bit plane transformation operations to provide machine learning model parameter compression. In some aspects, the method 400 provides additional detail for the block 315 of FIG. 3. In some aspects, the method 400 is performed by a compression system, such as the compression system 110 of FIG. 1.

At block 405, the compression system selects a bit position for the words used to encode the converted parameters. As discussed above, selecting the bit position may also be referred to as selecting a bit plane. Generally, the compression system may use any suitable technique to select the bit position (including randomly or pseudo-randomly), as each bit position will be similarly processed during the method 400. Although depicted as an iterative process for conceptual clarity (where each bit position is selected and evaluated sequentially), in some aspects, the compression system may process some or all of the bit positions in parallel.

At block 410, the compression system selects a word length to use for the selected bit position. That is, the compression system selects a word length to be used to encode the bit plane corresponding to the selected bit position. Generally, the word length may be selected using any suitable technique. In some aspects, the compression system may refer to a defined set or list of alternative word lengths (e.g., defined as a hyperparameter) and select the word length (at block 410) from this list (e.g., randomly or pseudo-randomly). For example, in some aspects, the set of alternative word lengths includes word lengths ranging from a minimum length (e.g., a word length of 2 or other value) to a maximum length (e.g., a word length of 256 or other value).

Although depicted as an iterative process for conceptual clarity (where each alternative word length is selected and evaluated sequentially), in some aspects, the compression system may process some or all of the word lengths in parallel. In some aspects, the compression system may reference a defined mapping to identify which word length to use for the selected bit position (without actively evaluating alternatives).

At block 415, the compression system generates a bit plane for the selected bit position based on the selected word length. That is, the compression system encodes the selected bit plane using words having the selected word length.

At block 420, the compression system determines the sparsity of the selected bit plane encoded at the selected word length. In some aspects, this is referred to as the bit plane sparsity or a sparsity value for the bit plane. In some aspects, the bit plane sparsity indicates the percentage of words (in the selected bit plane encoded at the selected word length) that have a value matching a defined value (such as 0, or a value equal to the mode of the words in the selected bit plane).

At block 425, the compression system determines whether there are any additional word length(s) that have not yet been used to evaluate the current bit position. If so, the method 400 returns to block 410. If not, the method 400 continues to block 430.

At block 430, the compression system determines a word length to be used for the selected bit position (e.g., once the compression system has evaluated all alternative word lengths for the current bit position. In some aspects, the compression system selects the word length that resulted in the highest bit plane sparsity. In some aspects, the compression system selects the largest word length that resulted in a bit plane sparsity above a defined threshold. In some aspects, the compression system selects the word length that results in the most compression when a bit mask is applied. For example, the compression system may select a word length that ensures the total number of bits used to encode the bit plane (after adding mask bits and removing words having a defined value such as 0) is minimized, or at least near the minimum. In some aspects, if the minimum bit plane sparsity is above a threshold (e.g., no word lengths resulted in a sparsity above the threshold), the compression system may determine that the bit mask operation will not be used for the bit plane (as discussed in more detail below), and thus the compression system may use one or more other criteria to determine the word length (e.g., based on hardware configurations or other preferences).

At block 435, the compression system determines whether there is at least one additional bit position that has not yet been evaluated. If so, the method 400 returns to block 405. If not, the method 400 terminates at block 440. In this way, the compression system can adaptively select or determine a word length for each bit position (e.g., for each bit plane) that maximizes, or at least increases, model compressibility.

### Example Method for Bit Masking Operations to Provide Machine Learning Model Parameter Compression

FIG. 5 is a flow diagram depicting an example method 500 for bit masking operations to provide machine learning model parameter compression. In some aspects, the method 500 provides additional detail for the block 320 of FIG. 3. In some aspects, the method 500 is performed by a compression system, such as the compression system 110 of FIG. 1.

At block 505, the compression system selects a bit plane. As discussed above, selecting the bit plane may also be referred to as selecting a bit position. Generally, the compression system may use any suitable technique to select the bit plane (e.g., randomly or pseudo-randomly), as each bit plane will be similarly processed during the method 500. Although depicted as an iterative process for conceptual clarity (where each bit plane is selected and evaluated sequentially), in some aspects, the compression system may process some or all of the bit planes in parallel.

At block 510, the compression system determines the sparsity of the selected bit plane. For example, as discussed above, the compression system may determine the percentage of words (used to encode the selected bit plane) that have a value that matches or is equal to a defined mask value (e.g., a value of 0, or a value equal to the statistical mode of the words used to encode the bit plane).

At block 515, the compression system determines whether one or more sparsity criteria are satisfied. The sparsity criteria may generally be used to determine whether using a masking operation for the bit plane should be performed. In some aspects, the sparsity criteria comprise a threshold amount of sparsity. For example, in some aspects, if the bit plane sparsity is below a threshold, adding the mask bit may actually increase the average size of each word in the bit plane, and the compression system may therefore determine that the sparsity criteria are not satisfied. As one example, if the bit plane words are eight bits long, the sparsity value should be at least 12.5%. If sparsity is less than this value, the bit masking will increase the size of the bit plane (e.g., increasing the total number of bits used to encode the bit plane), and the sparsity criteria may not be satisfied. If the sparsity is greater than this value, the masking operation will reduce the size of the bit plane, and the sparsity criteria may be satisfied. Generally, higher sparsity correlates to higher compressibility (e.g., a sparsity of 62.5% for 8-bit words may result in a compression factor of two, where the size of the bit plane is halved). The specific sparsity criteria may vary depending on the word size used to encode the bit plane and/or the implementation of the masking.

If, at block 515, the compression system determines that the criteria are not satisfied (e.g., the bit plane is not sufficiently sparse to warrant bit masking), the method 500 continues to block 530. If the compression system determines that the criteria are met, the method 500 continues to block 520.

At block 520, the compression system determines the mode value of the words used to encode the bit plane (e.g., the most common value). At block 525, the compression system then masks the bit plane based on that determined mode. For example, as discussed above, the compression system may replace all words having that mode value with a single mask bit having a defined value (e.g., a value of 1), and the compression system may append or prepend all other words with a single mask bit having another defined value (e.g., a value of 0). For example, suppose the mode value of a given bit plane is “01010101.” In some aspects, the compression system can replace any bit plane words having this mode value of “01010101” with a single mask bit having a value of one: “1.” Similarly, the compression system may append a mask bit with a value of zero to any bit plane words having a value different from the mode value (e.g., replacing bit plane word “10101010” with “010101010”).

At block 530, the compression system determines whether there is at least one additional bit plane that has not yet been evaluated. If so, the method 500 returns to block 505. If not, the method 500 terminates at block 535. In this way, the compression system can adaptively determine whether to use bit masking for each bit plane (e.g., for each bit position) in order to maximize, or at least increase, model compression.

### Example Method for Data Compression

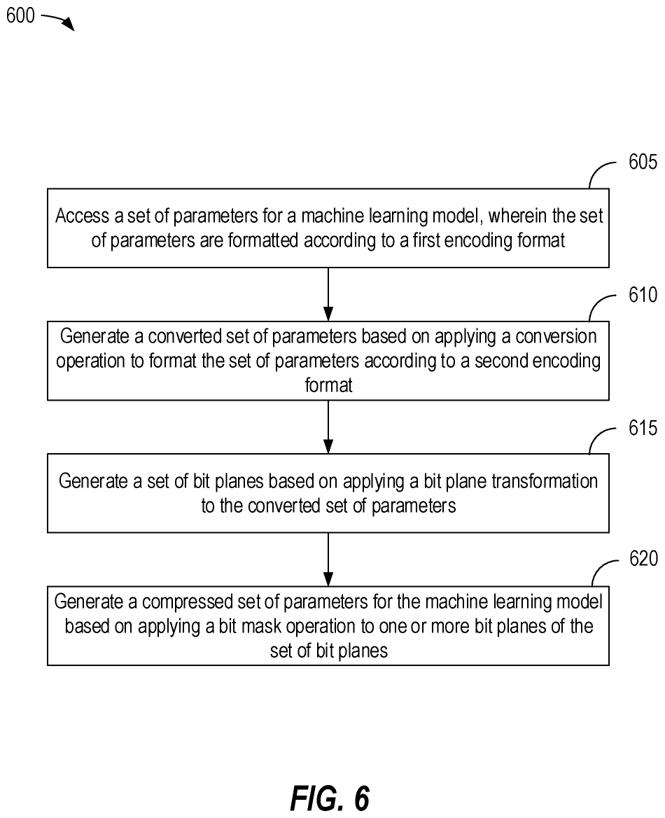

FIG. 6 is a flow diagram depicting an example method 600 for data compression. In some aspects, the method 600 is performed by a compression system, such as the compression system 110 of FIG. 1, the system that performs the operation 200 of FIG. 2, the system that performs the method 300 of FIG. 3, the system that performs the method 400 of FIG. 4, and/or the system that performs the method 500 of FIG. 5.

At block 605, a set of parameters for a machine learning model is accessed, wherein the set of parameters are formatted according to a first encoding format.

At block 610, a converted set of parameters is generated based on applying a conversion operation to format the set of parameters according to a second encoding format.

In some aspects, applying the conversion operation comprises identifying one or more parameters of the set of parameters that have a value of zero; and encoding each respective parameter of the one or more parameters without including a respective sign bit, wherein one or more other parameters having non-zero values are encoded with sign bits.

At block 615, a set of bit planes is generated based on applying a bit plane transformation to the converted set of parameters.

In some aspects, applying the bit plane transformation (at block 615) comprises, for each respective bit plane of the set of bit planes, determining a respective word length to encode the respective bit plane.

In some aspects, determining the respective word length to encode each respective bit plane comprises adaptively selecting a first word length for a first bit plane of the set of bit planes. The adaptively selecting may include encoding the first bit plane based on the first word length, determining a first sparsity value of the first bit plane encoded based on the first word length, encoding the first bit plane based on a second word length, determining a second sparsity value of the first bit plane encoded based on the second word length, and selecting the first word length for the first bit plane based on the first and second sparsity values.

At block 620, a compressed set of parameters for the machine learning model is generated based on applying a bit mask operation to one or more bit planes of the set of bit planes.

In some aspects, generating the compressed set of parameters (at block 620) includes determining to apply the bit mask operation to a first bit plane (of the set of bit planes) based on a first sparsity value of the first bit plane and determining to not apply the bit mask operation to a second bit plane (of the set of bit planes) based on a second sparsity value of the second bit plane.

In some aspects, the method 600 further includes (e.g., subsequent to block 615) determining a magnitude threshold, wherein the magnitude threshold is a hyperparameter; generating a pruned set of bit planes based on pruning one or more words used to encode the set of bit planes based on the magnitude threshold; decoding the pruned set of bit planes to generate a pruned set of parameters; updating one or more parameters of the pruned set of parameters using training data; and encoding the pruned set of parameters based on applying the conversion operation, the bit plane transformation, and the bit mask operation to generate a pruned compressed set of parameters.

In some aspects, pruning the one or more words used to encode the set of bit planes comprises: determining that the one or more words have a magnitude smaller than the magnitude threshold and setting each of the one or more words to a value of 0.

In some aspects, applying the bit mask operation (at block 620) comprises, for at least a first bit plane of the set of bit planes, determining a mode of a set of words used to encode the first bit plane and compressing the first bit plane based on the mode. Compressing the first bit plane may include identifying one or more words of the set of words that have values matching the mode and replacing each respective word of the one or more words with a respective mask bit indicating that the respective word has a value equal to the mode.

### Example Processing System for Data Compression

In some aspects, the workflows, techniques, and methods described with reference to FIGS. 1-6 may be implemented on one or more devices or systems. FIG. 7 depicts an example processing system 700 configured to perform various aspects of the present disclosure, including, for example, the techniques and methods described with respect to FIGS. 1-6. In some aspects, the processing system 700 may correspond to a compression system, such as the compression system 110 of FIG. 1. For example, the processing system 700 may correspond to a system that compiles machine learning models after training, trains machine learning models, and/or that uses machine learning models to inference during runtime. Although depicted as a single system for conceptual clarity, in some aspects, as discussed above, the operations described below with respect to the processing system 700 may be distributed across any number of devices or systems.

The processing system 700 includes a central processing unit (CPU) 702, which in some examples may be a multi-core CPU. Instructions executed at the CPU 702 may be loaded, for example, from a program memory associated with the CPU 702 or may be loaded from a memory partition (e.g., a partition of memory 724).

The processing system 700 also includes additional processing components tailored to specific functions, such as a graphics processing unit (GPU) 704, a digital signal processor (DSP) 706, a neural processing unit (NPU) 708, a multimedia component 710 (e.g., a multimedia processing unit), and a wireless connectivity component 712.

An NPU, such as NPU 708, is generally a specialized circuit configured for implementing the control and arithmetic logic for executing machine learning algorithms, such as algorithms for processing artificial neural networks (ANNs), deep neural networks (DNNs), random forests (RFs), and the like. An NPU may sometimes alternatively be referred to as a neural signal processor (NSP), tensor processing unit (TPU), neural network processor (NNP), intelligence processing unit (IPU), vision processing unit (VPU), or graph processing unit.

NPUs, such as the NPU 708, are configured to accelerate the performance of common machine learning tasks, such as image classification, machine translation, object detection, and various other predictive models. In some examples, a plurality of NPUs may be instantiated on a single chip, such as a system on a chip (SoC), while in other examples the NPUs may be part of a dedicated neural-network accelerator.

NPUs may be optimized for training or inference, or in some cases configured to balance performance between both. For NPUs that are capable of performing both training and inference, the two tasks may still generally be performed independently.

NPUs designed to accelerate training are generally configured to accelerate the optimization of new models, which is a highly compute-intensive operation that involves inputting an existing dataset (often labeled or tagged), iterating over the dataset, and then adjusting model parameters, such as weights and biases, in order to improve model performance. Generally, optimizing based on a wrong prediction involves propagating back through the layers of the model and determining gradients to reduce the prediction error.

NPUs designed to accelerate inference are generally configured to operate on complete models. Such NPUs may thus be configured to input a new piece of data and rapidly process this piece of data through an already trained model to generate a model output (e.g., an inference).

In some implementations, the NPU 708 is a part of one or more of the CPU 702, the GPU 704, and/or the DSP 706.

In some examples, the wireless connectivity component 712 may include subcomponents, for example, for third generation (3G) connectivity, fourth generation (4G) connectivity (e.g., 4G Long-Term Evolution (LTE)), fifth generation connectivity (e.g., 5G or New Radio (NR)), Wi-Fi connectivity, Bluetooth connectivity, and/or other wireless data transmission standards. The wireless connectivity component 712 is further coupled to one or more antennas 714.

The processing system 700 may also include one or more sensor processing units 716 associated with any manner of sensor, one or more image signal processors (ISPs) 718 associated with any manner of image sensor, and/or a navigation processor 720, which may include satellite-based positioning system components (e.g., GPS or GLONASS), as well as inertial positioning system components.

The processing system 700 may also include one or more input and/or output devices 722, such as screens, touch-sensitive surfaces (including touch-sensitive displays), physical buttons, speakers, microphones, and the like.

In some examples, one or more of the processors of the processing system 700 may be based on an ARM or RISC-V instruction set.

The processing system 700 also includes the memory 724, which is representative of one or more static and/or dynamic memories, such as a dynamic random access memory, a flash-based static memory, and the like. In this example, the memory 724 includes computer-executable components, which may be executed by one or more of the aforementioned processors of the processing system 700.

In particular, in this example, the memory 724 includes a conversion component 724A, a bit plane component 724B, a masking component 724C, a pruning component 724D, and a fine-tuning component 724E. The memory 724 further includes model parameters 724F for one or more models (e.g., the input parameters 105 of FIG. 1 and/or the compressed parameters 140 of FIG. 4). Although not included in the illustrated example, in some aspects the memory 724 may also include other data, such as training data (e.g., to train and/or fine-tune the model(s)). Though depicted as discrete components for conceptual clarity in FIG. 7, the illustrated components (and others not depicted) may be collectively or individually implemented in various aspects.

The processing system 700 further comprises a conversion circuit 726, a bit plane circuit 727, a masking circuit 728, a pruning circuit 729, and a fine-tuning circuit 730. The depicted circuits, and others not depicted, may be configured to perform various aspects of the techniques described herein.

For example, the conversion component 724A and/or the conversion circuit 726 (which may correspond to the conversion component 115 of FIG. 1) may be used to convert input parameters from a first format (e.g., two's-complement) to a second (e.g., sign-magnitude), as discussed above. For example, the conversion component 724A and/or the conversion circuit 726 may convert the parameters to another format that distributes the bit sparsity in a manner that facilitates compression.

The bit plane component 724B and/or the bit plane circuit 727 (which may correspond to the bit plane component 125 of FIG. 1) may be used to generate bit planes for converted (or input) parameters, as discussed above. For example, the bit plane component 724B and/or the bit plane circuit 727 may determine a defined, optimal, or desired bit plane word length and encode each bit plane based on the determined word lengths in order to maximize, or at least enhance, compressibility.

The masking component 724C and/or the masking circuit 728 (which may correspond to the masking component 135 of FIG. 1) may be used to apply bit masking operations, as discussed above. For example, the masking component 724C and/or the masking circuit 728 may add a mask bit to each bit plane word (generated by the bit plane component 724B and/or bit plane circuit 727) and remove any bit plane words having a value equal to a defined value (e.g., zero, or the mode value of the words in the bit plane).

The pruning component 724D and/or the pruning circuit 729 may be used to prune bit plane words, as discussed above. For example, the pruning component 724D and/or the pruning circuit 729 may compare each bit plane word to a defined threshold or range, and prune (e.g., set to 0) the bit plane words with a magnitude smaller than the threshold. As discussed above, this pruning of bit plane words (pruning individual bits from multiple parameters), rather than pruning an entire parameter word, may result in higher model accuracy, as compared to some conventional parameter pruning approaches.

The fine-tuning component 724E and/or the fine-tuning circuit 730 may be used to perform model updating or fine-tuning after bit plane pruning, as discussed above. For example, the fine-tuning component 724E and/or the fine-tuning circuit 730 may decode the pruned parameters, update the parameters using a relatively small set of training data, and re-encode these parameters (or allow the other components to re-encode these parameters).

Though depicted as separate components and circuits for clarity in FIG. 7, the conversion circuit 726, the bit plane circuit 727, the masking circuit 728, the pruning circuit 729, and the fine-tuning circuit 730 may collectively or individually be implemented in other processing devices of the processing system 700, such as within the CPU 702, the GPU 704, the DSP 706, the NPU 708, and the like.

Generally, the processing system 700 and/or components thereof may be configured to perform the methods described herein.

Notably, in other aspects, elements of the processing system 700 may be omitted, such as where the processing system 700 is a server computer or the like. For example, the multimedia component 710, the wireless connectivity component 712, the sensor processing units 716, the ISPs 718, and/or the navigation processor 720 may be omitted in other aspects. Further, aspects of the processing system 700 may be distributed between multiple devices.

### Example Clauses

Implementation examples are described in the following numbered clauses:

Clause 1: A method, comprising: accessing a set of parameters for a machine learning model, wherein the set of parameters are formatted according to a first encoding format; generating a converted set of parameters based on application of a conversion operation to format the set of parameters according to a second encoding format; generating a set of bit planes based on application of a bit plane transformation to the converted set of parameters; and generating a compressed set of parameters for the machine learning model based on application of a bit mask operation to one or more bit planes of the set of bit planes.

Clause 2: A method according to Clause 1, wherein applying the bit plane transformation comprises, for each respective bit plane of the set of bit planes, determining a respective word length to encode the respective bit plane.

Clause 3: A method according to Clause 2, wherein determining the respective word length to encode each respective bit plane comprises adaptively selecting a first word length for a first bit plane of the set of bit planes, the adaptively selecting comprising: encoding the first bit plane based on the first word length; determining a first sparsity value of the first bit plane encoded based on the first word length; encoding the first bit plane based on a second word length; determining a second sparsity value of the first bit plane encoded based on the second word length; and selecting the first word length for the first bit plane based on the first and second sparsity values.

Clause 4: A method according to any of Clauses 1-3, wherein generating the compressed set of parameters comprises: determining to apply the bit mask operation to a first bit plane of the set of bit planes, based on a first sparsity value of the first bit plane; and determining to not apply the bit mask operation to a second bit plane of the set of bit planes, based on a second sparsity value of the second bit plane.

Clause 5: A method according to any of Clauses 1-4, further comprising: generating a pruned set of bit planes based on pruning one or more words used to encode the set of bit planes based on a magnitude threshold, wherein the magnitude threshold is a hyperparameter; decoding the pruned set of bit planes to generate a pruned set of parameters; updating one or more parameters of the pruned set of parameters using training data; and encoding the pruned set of parameters based on applying the conversion operation, the bit plane transformation, and the bit mask operation to generate a pruned compressed set of parameters.

Clause 6: A method according to Clause 5, wherein pruning the one or more words used to encode the set of bit planes comprises: determining that the one or more words have a magnitude smaller than the magnitude threshold; and setting each of the one or more words to a value of zero.

Clause 7: A method according to any of Clauses 1-6, wherein applying the bit mask operation comprises, for at least a first bit plane of the set of bit planes: determining a mode of a set of words used to encode the first bit plane; and compressing the first bit plane based on the mode, comprising: identifying one or more words of the set of words that have values matching the mode; and replacing each respective word of the one or more words with a respective mask bit indicating that the respective word has a value equal to the mode.

Clause 8: A method according to any of Clauses 1-7, wherein applying the conversion operation comprises: identifying one or more parameters of the set of parameters that have a value of zero; and encoding each respective parameter of the one or more parameters without including a respective sign bit, wherein one or more other parameters having non-zero values are encoded with sign bits.

Clause 9: A processing system comprising: a memory comprising computer-executable instructions; and one or more processors configured to execute the computer-executable instructions and cause the processing system to perform a method in accordance with any of Clauses 1-8.

Clause 10: A processing system comprising means for performing a method in accordance with any of Clauses 1-8.

Clause 11: A non-transitory computer-readable medium comprising computer-executable instructions that, when executed by one or more processors of a processing system, cause the processing system to perform a method in accordance with any of Clauses 1-8.

Clause 12: A non-transitory computer-readable medium encoding logic that, when executed by a processing system, causes the processing system to perform a method in accordance with any of Clauses 1-8.

Clause 13: An apparatus comprising logic circuitry configured to perform a method in accordance with any of Clauses 1-8.

Clause 14: A computer program product embodied on a computer-readable storage medium comprising code for performing a method in accordance with any of Clauses 1-8.

### Additional Considerations

The preceding description is provided to enable any person skilled in the art to practice the various aspects described herein. The examples discussed herein are not limiting of the scope, applicability, or aspects set forth in the claims. Various modifications to these aspects will be readily apparent to those skilled in the art, and the generic principles defined herein may be applied to other aspects. For example, changes may be made in the function and arrangement of elements discussed without departing from the scope of the disclosure. Various examples may omit, substitute, or add various procedures or components as appropriate. For instance, the methods described may be performed in an order different from that described, and various steps may be added, omitted, or combined. Also, features described with respect to some examples may be combined in some other examples. For example, an apparatus may be implemented or a method may be practiced using any number of the aspects set forth herein. In addition, the scope of the disclosure is intended to cover such an apparatus or method that is practiced using other structure, functionality, or structure and functionality in addition to, or other than, the various aspects of the disclosure set forth herein. It should be understood that any aspect of the disclosure disclosed herein may be embodied by one or more elements of a claim.

As used herein, the word “exemplary” means “serving as an example, instance, or illustration.” Any aspect described herein as “exemplary” is not necessarily to be construed as preferred or advantageous over other aspects.

As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

As used herein, the term “determining” encompasses a wide variety of actions. For example, “determining” may include calculating, computing, processing, deriving, investigating, looking up (e.g., looking up in a table, a database or another data structure), ascertaining, and the like. Also, “determining” may include receiving (e.g., receiving information), accessing (e.g., accessing data in a memory), and the like. Also, “determining” may include resolving, selecting, choosing, establishing, and the like.

The methods disclosed herein comprise one or more steps or actions for achieving the methods. The method steps and/or actions may be interchanged with one another without departing from the scope of the claims. In other words, unless a specific order of steps or actions is specified, the order and/or use of specific steps and/or actions may be modified without departing from the scope of the claims. Further, the various operations of methods described above may be performed by any suitable means capable of performing the corresponding functions. The means may include various hardware and/or software component(s) and/or module(s), including, but not limited to a circuit, an application specific integrated circuit (ASIC), or processor. Generally, where there are operations illustrated in figures, those operations may have corresponding counterpart means-plus-function components with similar numbering.

The following claims are not intended to be limited to the aspects shown herein, but are to be accorded the full scope consistent with the language of the claims. Within a claim, reference to an element in the singular is not intended to mean “one and only one” unless specifically so stated, but rather “one or more.” Unless specifically stated otherwise, the term “some” refers to one or more. No claim element is to be construed under the provisions of 35 U.S.C. § 112(f) unless the element is expressly recited using the phrase “means for” or, in the case of a method claim, the element is recited using the phrase “step for.” All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims.

What is claimed is:

1. A processing system for data compression, comprising:
a memory comprising processor-executable instructions; and
one or more processors configured to execute the processor-executable instructions and cause the processing system to:
access a set of parameters for a machine learning model, wherein the set of parameters are formatted according to a first encoding format;
generate a converted set of parameters based on application of a conversion operation to format the set of parameters according to a second encoding format;
generate a set of bit planes based on application of a bit plane transformation to the converted set of parameters; and
generate a compressed set of parameters for the machine learning model based on application of a bit mask operation to one or more bit planes of the set of bit planes.

2. The processing system of claim 1, wherein, to apply the bit plane transformation, the one or more processors are configured to execute the processor-executable instructions to cause the processing system to, for each respective bit plane of the set of bit planes, determine a respective word length to encode the respective bit plane.

3. The processing system of claim 2, wherein, to determine the respective word length to encode each respective bit plane, the one or more processors are configured to execute the processor-executable instructions to cause the processing system to:
encode a first bit plane of the set of bit planes based on a first word length;
determine a first sparsity value of the first bit plane encoded based on the first word length;
encode the first bit plane based on a second word length;
determine a second sparsity value of the first bit plane encoded based on the second word length; and
select the first word length for the first bit plane based on the first and second sparsity values.

4. The processing system of claim 1, wherein, to generate the compressed set of parameters, the one or more processors are configured to execute the processor-executable instructions to cause the processing system to:
determine to apply the bit mask operation to a first bit plane of the set of bit planes, based on a first sparsity value of the first bit plane; and
determine to not apply the bit mask operation to a second bit plane of the set of bit planes, based on a second sparsity value of the second bit plane.

5. The processing system of claim 1, wherein the one or more processors are configured to further execute the processor-executable instructions to cause the processing system to:
generate a pruned set of bit planes based on pruning of one or more words used to encode the set of bit planes based on a magnitude threshold, wherein the magnitude threshold is a hyperparameter;
decode the pruned set of bit planes to generate a pruned set of parameters;
update one or more parameters of the pruned set of parameters using training data; and
encode the pruned set of parameters based on application of the conversion operation, the bit plane transformation, and the bit mask operation to generate a pruned compressed set of parameters.

6. The processing system of claim 5, wherein, to prune the one or more words used to encode the set of bit planes, the one or more processors are configured to execute the processor-executable instructions to cause the processing system to:
determine that the one or more words have a magnitude smaller than the magnitude threshold; and
set each of the one or more words to a value of zero.

7. The processing system of claim 1, wherein, to apply the bit mask operation, the one or more processors are configured to execute the processor-executable instructions to cause the processing system to, for at least a first bit plane of the set of bit planes:
determine a mode of a set of words used to encode the first bit plane; and
compress the first bit plane based on the mode, wherein, to compress the first bit plane based on the mode, the one or more processors are configured to execute the processor-executable instructions to cause the processing system to:
identify one or more words of the set of words that have values matching the mode; and
replace each respective word of the one or more words with a respective mask bit indicating that the respective word has a value equal to the mode.

8. The processing system of claim 1, wherein, to apply the conversion operation, the one or more processors are configured to execute the processor-executable instructions to cause the processing system to:
identify one or more parameters of the set of parameters that have a value of zero; and
encode each respective parameter of the one or more parameters without including a respective sign bit, wherein one or more other parameters having non-zero values are encoded with sign bits.

9. A non-transitory computer-readable medium for data compression, the non-transitory computer-readable medium encoding logic that, when executed by a processing system, causes the processing system to:
access a set of parameters for a machine learning model, wherein the set of parameters are formatted according to a first encoding format;
generate a converted set of parameters based on application of a conversion operation to format the set of parameters according to a second encoding format;
generate a set of bit planes based on application of a bit plane transformation to the converted set of parameters; and
generate a compressed set of parameters for the machine learning model based on application of a bit mask operation to one or more bit planes of the set of bit planes.

10. The non-transitory computer-readable medium of claim 9, wherein, to apply the bit plane transformation, the processing system is configured to execute the logic to cause the processing system to, for each respective bit plane of the set of bit planes, determine a respective word length to encode the respective bit plane.

11. The non-transitory computer-readable medium of claim 10, to determine the respective word length to encode each respective bit plane, the processing system is configured to execute the logic to cause the processing system to:
encode a first bit plane of the set of bit planes based on a first word length;
determine a first sparsity value of the first bit plane encoded based on the first word length;
encode the first bit plane based on a second word length;
determine a second sparsity value of the first bit plane encoded based on the second word length; and
select the first word length for the first bit plane based on the first and second sparsity values.

12. The non-transitory computer-readable medium of claim 9, wherein, to generate the compressed set of parameters, the processing system is configured to execute the logic to cause the processing system to:
determine to apply the bit mask operation to a first bit plane of the set of bit planes, based on a first sparsity value of the first bit plane; and
determine to not apply the bit mask operation to a second bit plane of the set of bit planes, based on a second sparsity value of the second bit plane.

13. The non-transitory computer-readable medium of claim 9, wherein, to apply the bit mask operation, the processing system is configured to execute the logic to cause the processing system to, for at least a first bit plane of the set of bit planes:
determine a mode of a set of words used to encode the first bit plane; and
compress the first bit plane based on the mode, wherein, to compress the first bit plane based on the mode, the processing system is configured to execute the logic to cause the processing system to:
identify one or more words of the set of words that have values matching the mode; and
replace each respective word of the one or more words with a respective mask bit indicating that the respective word has a value equal to the mode.

14. The non-transitory computer-readable medium of claim 9, wherein, to apply the conversion operation, the processing system is configured to execute the logic to cause the processing system to:
identify one or more parameters of the set of parameters that have a value of zero; and
encode each respective parameter of the one or more parameters without including a respective sign bit, wherein one or more other parameters having non-zero values are encoded with sign bits.

15. An apparatus for data compression, the apparatus comprising logic circuitry configured to:
access a set of parameters for a machine learning model, wherein the set of parameters are formatted according to a first encoding format;
generate a converted set of parameters based on application of a conversion operation to format the set of parameters according to a second encoding format;
generate a set of bit planes based on application of a bit plane transformation to the converted set of parameters; and
generate a compressed set of parameters for the machine learning model based on application of a bit mask operation to one or more bit planes of the set of bit planes.

16. The apparatus of claim 15, wherein, to apply the bit plane transformation, the logic circuitry is configured to, for each respective bit plane of the set of bit planes, determine a respective word length to encode the respective bit plane.

17. The apparatus of claim 16, wherein, to determine the respective word length to encode each respective bit plane, the logic circuitry is configured to:
encode a first bit plane of the set of bit planes based on a first word length;
determine a first sparsity value of the first bit plane encoded based on the first word length;
encode the first bit plane based on a second word length;
determine a second sparsity value of the first bit plane encoded based on the second word length; and
select the first word length for the first bit plane based on the first and second sparsity values.

18. The apparatus of claim 15, wherein, to generate the compressed set of parameters, the logic circuitry is configured to:
determine to apply the bit mask operation to a first bit plane of the set of bit planes, based on a first sparsity value of the first bit plane; and
determine to not apply the bit mask operation to a second bit plane of the set of bit planes, based on a second sparsity value of the second bit plane.

19. The apparatus of claim 15, wherein the logic circuitry is further configured to:
generate a pruned set of bit planes based on pruning of one or more words used to encode the set of bit planes based on a magnitude threshold, wherein the magnitude threshold is a hyperparameter;
decode the pruned set of bit planes to generate a pruned set of parameters;
update one or more parameters of the pruned set of parameters using training data; and
encode the pruned set of parameters based on application of the conversion operation, the bit plane transformation, and the bit mask operation to generate a pruned compressed set of parameters.

20. The apparatus of claim 19, wherein, to prune the one or more words used to encode the set of bit planes, the logic circuitry is configured to:
determine that the one or more words have a magnitude smaller than the magnitude threshold; and
set each of the one or more words to a value of zero.

21. The apparatus of claim 15, wherein, to apply the bit mask operation, the logic circuitry is configured to, for at least a first bit plane of the set of bit planes:
determine a mode of a set of words used to encode the first bit plane; and
compress the first bit plane based on the mode, wherein, to compress the first bit plane based on the mode, the logic circuitry is configured to:
identify one or more words of the set of words that have values matching the mode; and
replace each respective word of the one or more words with a respective mask bit indicating that the respective word has a value equal to the mode.

22. The apparatus of claim 15, wherein, to apply the conversion operation, the logic circuitry is configured to:
identify one or more parameters of the set of parameters that have a value of zero; and
encode each respective parameter of the one or more parameters without including a respective sign bit, wherein one or more other parameters having non-zero values are encoded with sign bits.

23. A processor-implemented method for data compression, comprising:
accessing a set of parameters for a machine learning model, wherein the set of parameters are formatted according to a first encoding format;
generating a converted set of parameters based on applying a conversion operation to format the set of parameters according to a second encoding format;
generating a set of bit planes based on applying a bit plane transformation to the converted set of parameters; and
generating a compressed set of parameters for the machine learning model based on applying a bit mask operation to one or more bit planes of the set of bit planes.

24. The processor-implemented method of claim 23, wherein applying the bit plane transformation comprises, for each respective bit plane of the set of bit planes, determining a respective word length to encode the respective bit plane.

25. The processor-implemented method of claim 24, wherein determining the respective word length to encode each respective bit plane comprises adaptively selecting a first word length for a first bit plane of the set of bit planes, the adaptively selecting comprising:
encoding the first bit plane using the first word length;
determining a first sparsity value of the first bit plane encoded using the first word length;
encoding the first bit plane using a second word length;
determining a second sparsity value of the first bit plane encoded using the second word length; and
selecting the first word length for the first bit plane based on the first and second sparsity values.

26. The processor-implemented method of claim 23, wherein generating the compressed set of parameters comprises:
determining to apply the bit mask operation to a first bit plane of the set of bit planes, based on a first sparsity value of the first bit plane; and
determining to not apply the bit mask operation to a second bit plane of the set of bit planes, based on a second sparsity value of the second bit plane.

27. The processor-implemented method of claim 23, further comprising:
generating a pruned set of bit planes based on pruning one or more words used to encode the set of bit planes based on a magnitude threshold, wherein the magnitude threshold is a hyperparameter;
decoding the pruned set of bit planes to generate a pruned set of parameters;
updating one or more parameters of the pruned set of parameters using training data; and
encoding the pruned set of parameters based on applying the conversion operation, the bit plane transformation, and the bit mask operation to generate a pruned compressed set of parameters.

28. The processor-implemented method of claim 27, wherein pruning the one or more words used to encode the set of bit planes comprises:
determining that the one or more words have a magnitude smaller than the magnitude threshold; and
setting each of the one or more words to a value of zero.

29. The processor-implemented method of claim 23, wherein applying the bit mask operation comprises, for at least a first bit plane of the set of bit planes:
determining a mode of a set of words used to encode the first bit plane; and
compressing the first bit plane based on the mode, comprising:
identifying one or more words of the set of words that have values matching the mode; and
replacing each respective word of the one or more words with a respective mask bit indicating that the respective word has a value equal to the mode.

30. The processor-implemented method of claim 23, wherein applying the conversion operation comprises:
identifying one or more parameters of the set of parameters that have a value of zero; and
encoding each respective parameter of the one or more parameters without including a respective sign bit, wherein one or more other parameters having non-zero values are encoded with sign bits.
